(19) United States
(12) Patent Application Publication
(10) Pub. No.: US 2017/0255310 A1
(43) Pub. Date: Sep. 7, 2017

(54) DISPLAY DEVICE

(71) Applicant: Japan Display Inc., Minato-ku (JP)

(72) Inventors: Mitsuhide MIYAMOTO, Minato-ku (JP); Chunche MA, Minato-ku (JP)

(73) Assignee: Japan Display Inc., Minato-ku (JP)

(21) Appl. No.: 15/446,461

(22) Filed: Mar. 1, 2017

(30) Foreign Application Priority Data
Mar. 7, 2016 (JP) 2016-043910

(51) Int. Cl. G06F 3/041; H01L 27/32; G06F 3/044

(52) U.S. Cl. CPC G06F 3/0412; G06F 3/044; G06F 3/0416; H01L 27/323

(57) ABSTRACT

A display device includes a display area having a plurality of pixels arranged in a matrix, each of the plurality of pixels including a light emitting element and a transistor, and a touch sensor provided over the display area. The touch sensor includes a plurality of first electrodes and a plurality of second electrodes, and the plurality of first electrodes has a shape of ring-shaped electrodes connected to each other.

### CROSS-REFERENCE TO RELATED APPLICATION

The present application claims priority from Japanese application JP2016-043910 filed on Mar. 7, 2016, the content of which is hereby incorporated by reference into this application.

### BACKGROUND OF THE INVENTION

1. Field of the Invention

The present invention relates to a display device. Particularly the invention relates to a display device equipped with a touch sensor over a display area where an organic EL element is formed.

2. Description of the Related Art

It is demanded that a display device for a mobile device should be reduced in thickness and weight. In view of this, when a liquid crystal display device and an organic EL display device are compared, the organic EL display device is considered more advantageous in that it needs no backlight. Also, as the development of techniques for forming a pixel drive circuit and an organic EL element on a flexible substrate has been underway, a thinner and lighter display than a conventional display using a glass substrate has been realized. In this course of events, a reduction in thickness of members other than the display device, such as the touch sensor and the polarizer, is demanded as well. Particularly, the thickness increases if the touch sensor is bonded and mounted on the display device as a separate member. Therefore, a touch sensor as a built-in member of the display device is demanded.

A method for providing a built-in touch sensor in the organic EL display device is disclosed in Japanese Patent No. 5,778,961. According to this invention, it is disclosed that one of the electrodes forming the organic EL element is formed in the shape of a band and used as an electrode of the touch sensor. Meanwhile, JP 2014-56566 A discloses a configuration in which a layer with a low dielectric constant is provided between a touch sensor and a display device.

### SUMMARY OF THE INVENTION

Providing the built-in touch sensor in the organic EL display device raises new problems. One of these problems is that, due to the shorter distance between the electrode of the touch sensor and the organic EL element, the noise caused by the signal input to and circuit operation of a pixel drive circuit which drives the organic EL element may increase. This causes a reduction in S/N ratio of the touch sensor and deterioration in sensing performance. The organic EL layer is a multilayer structure made up of a plurality of layers. It is common that a cathode or anode conductive film is uniformly formed on the top layer. The parasitic capacitance acting between this conductive film and the neighboring layer increases.

Since the increase in parasitic capacitance leads to an increase in time constant and a reduction in detection signal level, sensing performance deteriorates due to an increase in detection time and a reduction in S/N ratio. Although it is possible to employ a configuration which reduces parasitic capacitance by inserting a layer with a low dielectric constant as in JP 2014-56566 A, problems remain with reducing thickness and an additional member is needed.

In view of the foregoing circumstances, the invention is to propose a configuration which suitably reduces parasitic capacitance by improving the electrode structure of a touch sensor, and provide a display device having this configuration.

A display device includes a display area having a plurality of pixels arranged in a matrix, each of the plurality of pixels including a light emitting element and a transistor, and a touch sensor provided over the display area. The touch sensor includes a plurality of first electrodes and a plurality of second electrodes, and the plurality of first electrodes has a shape of ring-shaped electrodes connected to each other.

### BRIEF DESCRIPTION OF THE DRAWINGS

FIG. 1 schematically shows a display device according to the invention.

FIGS. 2A and 2B schematically show built-in touch electrodes in the display device.

FIG. 3 shows the cross-sectional structure of the display device.

FIGS. 4A and 4B show an example of the shape of electrodes of a touch sensor according to the invention.

FIG. 5 shows the relation between the shape of the detection electrode and electrostatic capacitance.

FIG. 6 shows an example of the shape of electrodes of a touch sensor according to the invention.

FIG. 7 shows an example of the shape of electrodes of a touch sensor according to the invention.

FIG. 8 shows an example of the shape of electrodes of a touch sensor according to the invention.

FIG. 9 shows an example of the shape of electrodes of a touch sensor according to the invention.

FIG. 10 shows an example of the shape of electrodes of a touch sensor according to the invention.

### DETAILED DESCRIPTION OF THE INVENTION

Hereinafter, each embodiment of the invention will be described with reference to the drawings. In the drawings, the width, thickness, shape and the like of each part may be schematically illustrated, compared with the actual configuration, in order to clarify the explanation. However, such illustrations are simply an example and should not limit the interpretation of the invention. Also, in the specification and the drawings, components similar to those described before in drawings that are already mentioned may be denoted by the same reference signs and not described further in detail.

In the invention, when describing a configuration in which one structure is arranged over another structure, if simply the term “over” is used, it includes both the case where one structure is arranged directly upward from and in contact with another structure and the case where one structure is arranged above the another structure with still another structure in-between, unless stated otherwise.

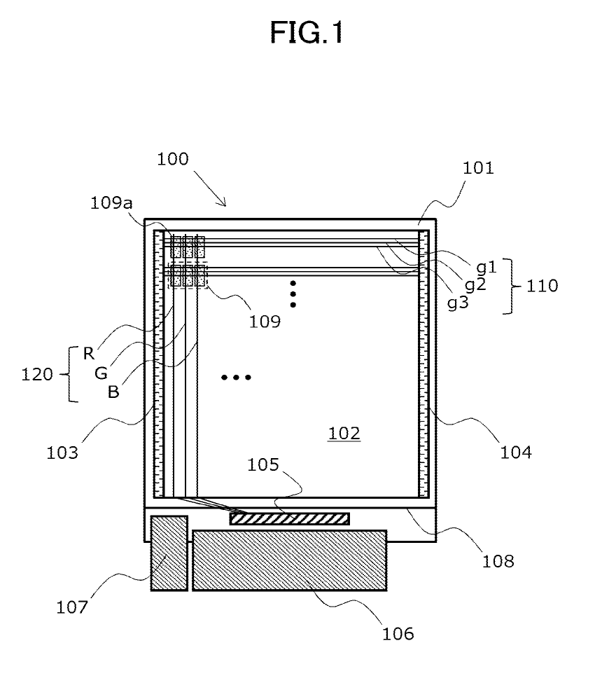

FIG. 1 shows an example of the configuration of a display device according to the invention. In a display device 100, a display area 102 and scanning line drive circuits 103, 104 are formed over a substrate 101, and a drive IC 105, a display FPC (flexible printed circuit board) 106, and a touch FPC 107 are connected to the substrate 101. In FIG. 1, the drive IC 105 is mounted over the substrate 101. However, the drive IC 105 may also be mounted over the display FPC 106. Also, a counter substrate 108 may be provided in such a way as to cover the display area 102. In the display area 102, a plurality of scanning lines laid in the direction of row (in FIG. 1, horizontal direction) and a plurality of video signal lines laid in the direction of column (in FIG. 1, vertical direction) are arranged. A subpixel 109a is arranged at the intersection of a scanning line and a video signal line. Each subpixel 109a has a light emitting element which emits light in a different color from other subpixels. A plurality of such subpixels 109a is gathered to form one pixel 109 (in FIG. 1, indicated by dotted-line frames), thus performing full-color display. In this example, three scanning lines 110 (g1, g2, g3) are arranged per line of pixels, and three video signal lines 120 (R, G, B) are arranged per column of pixels. Although not illustrated, wirings such as a power supply line for supplying a predetermined voltage to the light emitting elements are provided in the display area 102. In each subpixel 109a, a pixel circuit which controls the luminance of the light emitting element is provided so as to emit light with a luminance corresponding to a signal supplied from the drive IC 105 via the video signal line 120.

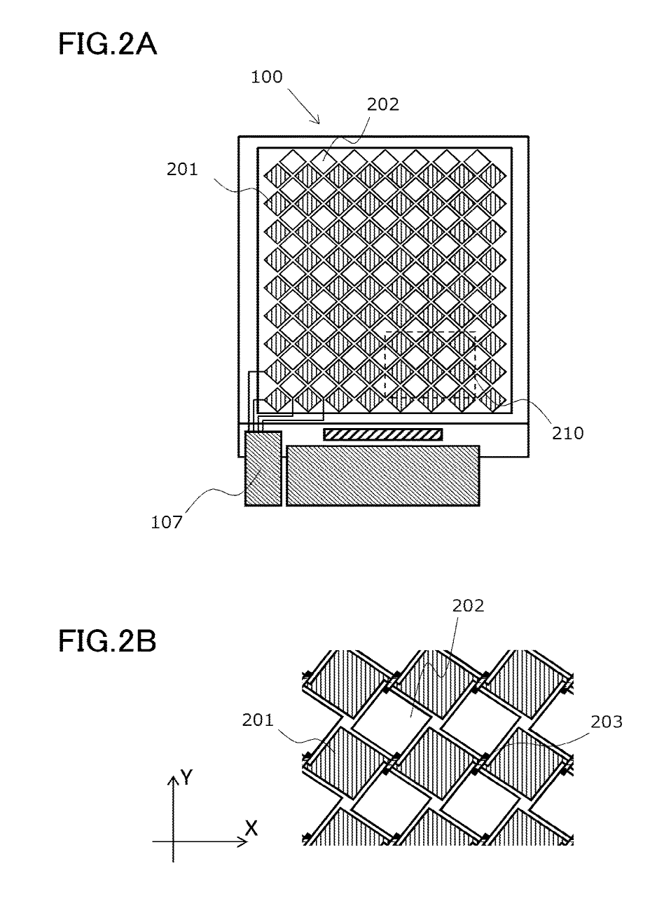

The display device 100 has a touch sensor in addition to the display function. Although the touch sensor is omitted from FIG. 1 in order to explain the display function in particular, the touch sensor is arranged in an upper layer of the light emitting element, that is, closer to the display surface side than the light emitting element, as shown in FIG. 2A. The touch sensor is made up of two kinds of electrodes, for example. One is a drive electrode 201 laid in the direction of row, and the other is a detection electrode 202 laid in the direction of column.

FIG. 2B shows an enlarged view of a dotted-line frame 210 shown in FIG. 2A. In FIG. 2B, an X-direction corresponds to the direction of row, and a Y-direction corresponds to the direction of column. The drive electrodes 201 and the detection electrodes 202 are provided over the display area of the display device 100 and therefore formed of a transparent conductive film of ITO (indium tin oxide), IZO (indium zinc oxide) or the like. Other materials forming the transparent conductive film may include an Ag nanowire or the like. The Ag nanowire is a material formed by dispersing Ag in the form of fine fiber into a solvent, and can be formed by coating. Moreover, the space between electrodes of one kind is arranged over the electrodes of the other kind and therefore these electrodes are connected by a bridge wire 203 or the like. In FIG. 2B, the electrodes are rectangular. However, the shape of the drive electrodes and the detection electrodes is not limited to this. When this touch sensor is touched at a predetermined position, the capacitance between the drive electrode and the detection electrode at that position changes, and this change in capacitance is detected, thus detecting the touched position. Each electrode is connected to a touch drive circuit and a detection circuit by the touch FPC 107.

The touch sensor shown in FIG. 2B is a mutual capacitance-type touch sensor. A touch drive circuit inputs a drive signal to the drive electrode. The drive signal is a pulse-like signal which rises and falls. With such rises and falls, the potential of the detection electrode fluctuates via the coupling with the drive electrode. The fluctuation in potential of the detection electrode is amplified and detected by a detection circuit, thus determining whether there is a touch or not.

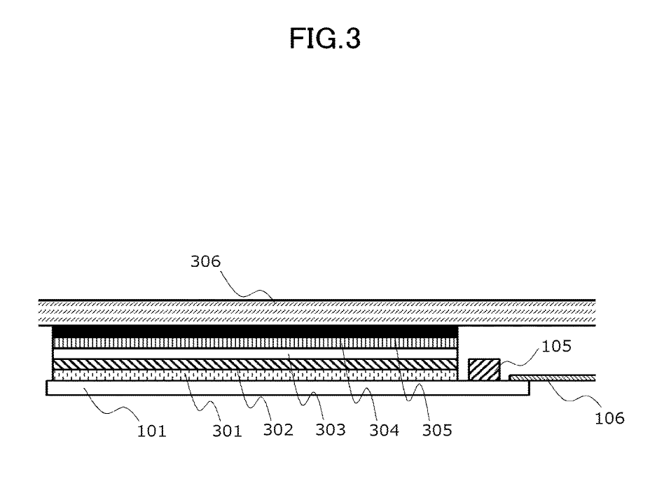

FIG. 3 shows an example of the cross-sectional structure of the display device equipped with the touch sensor. From the bottom in FIG. 3, the substrate 101, a TFT array 301, a light emitting element layer 302, a sealing layer 303, a touch sensor 304, a circular polarizer 305, and a cover glass 306 are arranged. An adhesive layer that is needed in the case of bonding the respective layers is not described. The cover glass 306 extends not only over the display area but also over the area where the driver IC 105 and the display FPC 106 are mounted.

In this structure, the touch sensor 304 is arranged over the TFT array 301 and the light emitting element layer 302 via the sealing layer 303. In the case where the substrate on which the touch sensor 304 is formed is reduced in thickness or in the case where the drive electrode and the detection electrode of the touch sensor are formed directly on the sealing layer 303, the touch sensor 304, and the electrodes included in the TFT array 301 and the light emitting element layer 302 are arranged very closely to each other. Consequently, an electrically strong capacitive coupling is formed between the touch sensor 304 and these electrodes. With a display operation, various signals are inputted to the TFT array 301 and the internal circuit operates. However, these signals and changes in potential at the time of circuit operation cause a noise, thus lowering the S/N ratio of the touch sensor 304. Moreover, with this parasitic capacitance, the time constants of the drive electrode and the detection electrode increase and therefore the touch detection operation itself takes a longer time.

A detection signal of the touch sensor is the result of detecting a change in potential occurring at the detection electrode by capacitive coupling when a drive signal is applied to one drive electrode. The amount of change ΔVsense in the detection signal of the touch sensor is expressed by the following equation, where Cp is the parasitic capacitance with respect to the detection electrode, Cxy is the coupling capacitance between the drive electrode and the detection electrode, n is the number of drive electrodes intersecting with the detection electrode, and Vin is the amplitude of the drive signal applied to the drive electrode.

$$Δ Vsense = Vin \cdot \frac{Cxy}{( nCxy + Cp )}$$

Since the parasitic capacitance Cp is the denominator of the equation, the detection signal drops as the parasitic capacitance increases.

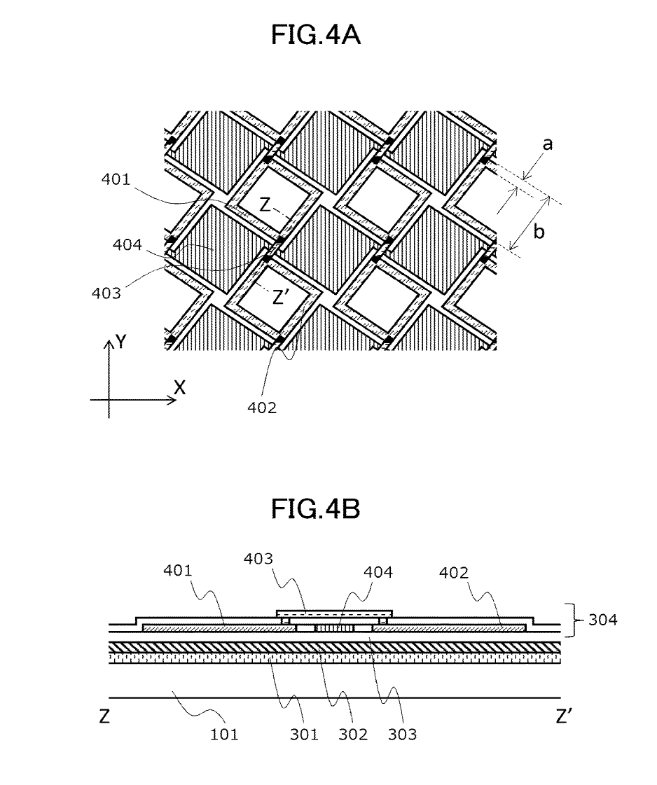

According to the invention, a new structure of the detection electrode is proposed in order to suitably reduce the parasitic capacitance at the detection electrode. FIGS. 4A and 4B show an example of the configuration according to the invention. FIG. 4A shows a planar configuration of touch sensor electrodes, similarly to FIG. 2B. FIG. 4B shows the cross-sectional structure taken along Z-Z′ shown in FIG. 4A.

In FIG. 4B, the substrate 101, the TFT array 301, the light emitting element layer 302, and the sealing layer 303 are similar to those shown in FIG. 3. FIG. 4B shows the structure of the touch sensor 304 more in detail. Detection electrodes 401, 402 and a drive wire 404 are arranged in the same layer. The detection electrodes 401 and 402 are connected by a bridge wire 403 laid over the drive wire 404.

As shown in FIG. 4A, the detection electrodes 401, 402 are ring-shaped. Specifically, a ring-shape with a hollow inner area and with the outer peripheral shape of the electrode being left as it is, is employed. Since the electrode area is smaller than that of a detection electrode with a solid inner area as in the conventional technique, the parasitic capacitance Cp between the detection electrode and the underlying light emitting element layer 302 and the like can be reduced.

Now, the shape of the detection electrodes 401, 402 will be described. When reducing the area of the detection electrode in order to reduce parasitic capacitance, simply reducing the shape has a similar effect. However, the coupling capacitance Cxy between the drive electrode and the detection electrode, which is important in the touch detection operation, contributes significantly in the area where the two electrodes come most closely to each other, that is, in peripheral edge parts of the electrodes. Therefore, by making hollow the inner area of the detection electrode and thus reducing the area, it is possible to suitably reduce the parasitic capacitance Cp without reducing the coupling capacitance Cxy.

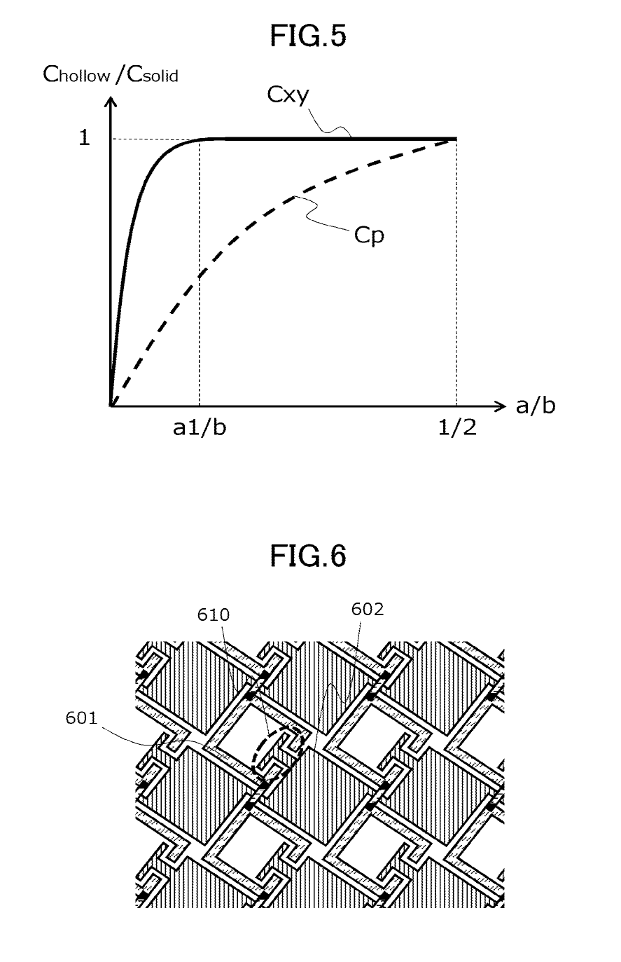

FIG. 5 shows changes in the parasitic capacitance Cp and the coupling capacitance Cxy in the case where the detection electrode is ring-shaped and in the case where the detection electrode has a conventional shape. In FIG. 4A, the width of the ring in the case where the detection electrode is ring-shaped is expressed by a, and the full width of the detection electrode is expressed by b. In FIG. 5, the ratio of the two a/b is taken on the horizontal axis. In the case of the conventional shape without any hollow part, a/b=1/2 is the maximum. Also, the ratio of the coupling capacitances (Chollow/Csolid) in the case where the detection electrode is ring-shaped and in the case where the detection electrode has the conventional shape is taken on the vertical axis. If the two coupling capacitances are equal, (Chollow/Csolid)=1 is the maximum.

If the width a of the ring is increased while the full width b of the detection electrode is kept constant, the parasitic capacitance Cp increases as the area of the detection electrode increases. Meanwhile, the ratio of the coupling capacitances reaches substantially 1:1 with respect to the conventional shape, when the width a of the ring reaches a certain value. That is, if the width al of the ring at this time is defined as a minimum value and the shape of the detection electrode is decided in such a way as to achieve this value or above, the parasitic capacitance Cp can be suitably reduced while the coupling capacitance Cxy is maintained. Thus, large amplitude of the detection signal can be realized.

As an example, in a system where a cover glass with a dielectric constant of 5.7 and a thickness of 700 μm is provided over the touch sensor shown in FIG. 4A, if the full width b of the detection electrode is 3 mm, the result of the calculation is a1=800 μm. That is, with a ring-shaped structure in which a 1.4-mm-diameter hole is provided inside a 3-mm-diameter detection electrode, a configuration which suitably reduces parasitic capacitance while maintaining the coupling capacitance with the drive electrode at a level equal to that in the conventional configuration can be realized.

This structure also has the effect of reducing a noise from the TFT array 301 driving the light emitting element layer 302, in addition to the reduction in parasitic capacitance. The noise due to the drive signal of the TFT array 301 is transmitted to the detection electrodes 401, 402 via the light emitting element layer 302. However, with the reduction in the electrode area, the capacitive coupling can be reduced and the noise can be reduced.

Now, a method for forming the touch sensor shown in FIGS. 4A and 4B will be described. Here, the process of forming the TFT array 301, the light emitting element layer 302, and the sealing layer 303 is omitted.

The detection electrodes 401, 402 and the drive electrodes 404 are formed on a sealing film surface. Here, after depositing a transparent conductive material such as ITO or IZO by sputtering, these electrodes are formed by a photolithography process. Since the sealing layer 303 formed over the light emitting element layer 302 has sufficient coatability and contactability, it is possible to apply the process as described above, even after the light emitting element layer 302 is formed. Instead of the foregoing transparent conductive material, a material containing silver nanowires may be printed to form the detection electrodes 401, 402 and the drive electrodes 404. Next, after an insulation film is formed, a contact hole reaching the detection electrodes 401, 402 is formed and the bridge electrode 403 is formed. The bridge electrode 403 has a small area and therefore is not very visible. Thus, after a metal such as aluminum, silver, or copper is deposited in order to prioritize a reduction in resistance, the bridge electrode 403 is formed by a photolithography process. After that, the electrode pattern may be protected further by forming an insulation film or by bonding a film or the like, if necessary. By these processes, the touch sensor can be formed over the display area.

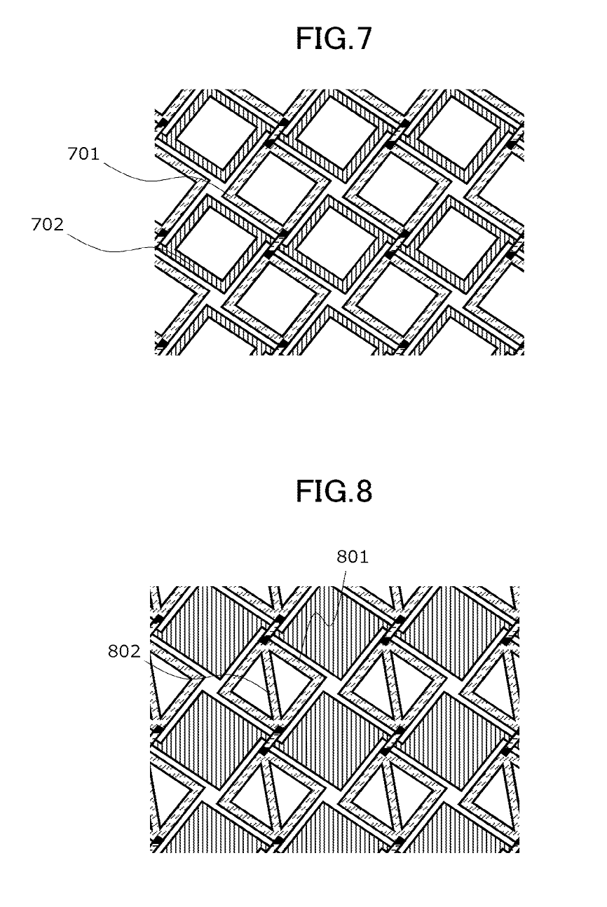

As other examples of the invention, structures as shown in FIGS. 6 and 7 may be employed as well. In FIG. 6, a cut-out is provided at a part of a ring-shaped detection electrode 601, and a drive electrode 602 has a protruding part 610 via this cut-out. The protruding part 610 enters the inside of the ring. The parasitic capacitance of the detection electrode 601 can be reduced and the coupling capacity can be increased between the protruding part 610 and the detection electrode 601. FIG. 7 shows an example in which, in addition to a detection electrode 701, a drive electrode 702 is ring-shaped as well. The drive electrode is driven with low impedance and therefore is not so susceptible to the influence of external electric field fluctuations than the detection electrode. However, in the drive electrode is formed of a transparent conductive material, it has a higher resistance than metal. Therefore, a central area within the plane, that is, an area distant from the circuit which drives the drive electrode, is more susceptible to the influence of a noise from the TFT array or the like. By forming the drive electrode 702 in a ring-shape, it is possible to reduce the influence of the noise and to perform stable touch detection in the entire area within the plane.

FIG. 8 shows a still another configuration example that is different from the above. A rib 802 is provided on a diagonal line in ring-shaped detection electrode 801. The time constant can be reduced, compared with a ring-shaped detection electrode.

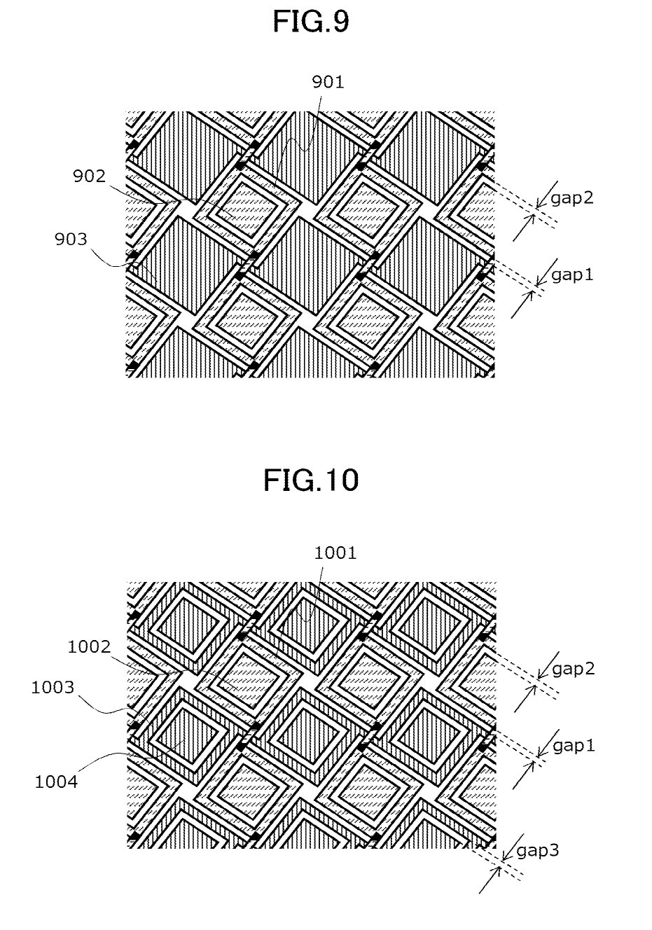

As described above, if the detection electrode or the drive electrode is ring-shaped, significant improvement in electrical functions can be expected, whereas the area where the drive electrode is provided and the area where the drive electrode is not provided are separated and a difference in refractive index may occur between these areas, causing the ring-shape of the detection electrode to be visible in some cases. Thus, on the inner side of a ring-shaped detection electrode 901, an internal electrode 902 is formed of the material in the same layer as the detection electrode 901, as shown in FIG. 9. As the internal electrode 902 is provided, the refractive index within the plane can be made uniform and therefore the visibility of the detection electrode can be lowered.

The internal electrode 902 is insulated from both of the detection electrode 901 and a drive electrode 903 and is in a floating state. However, if the distance between the internal electrode 902 and the detection electrode 901 is short, a parasitic capacitance may be generated between the detection electrode 901 and the light emitting element layer 302 via the internal electrode 902 in some cases.

If the distance between the ring-shaped detection electrode 901 and the drive electrode 903 is gap1 and the distance between the ring-shaped detection electrode 901 and the internal electrode 902 is gap2, it is desirable that gap1 is narrow since gap1 influences the coupling capacitance between the detection electrode and the drive electrode. In view of the visibility of the ring-shaped detection electrode, it is desirable that gap2 is narrow. However, if gap2 is narrowed, the parasitic capacitance increases between the ring-shaped detection electrode 901 and the light emitting element layer 302 via the internal electrode 902. Therefore, it is preferable that gap2 is broader than gap1.

FIG. 10 shows an example in which the ring-shape and the internal electrode provided on the detection electrode are applied to the drive electrode side as well. An internal electrode 1002 is formed on the inner side of a ring-shaped detection electrode 1001, and an internal electrode 1004 is formed on the inner side of a ring-shaped drive electrode 1003.

The distance between the ring-shaped drive electrode 1002 and the internal electrode 1004 is gap3. Since the drive electrode 1002 receives less influence of the noise from the TFT array 301 or the light emitting element layer 302 than the detection electrode 1001, gap3 may be smaller than gap2. The relation between these distances may be gap1<gap3≦gap2 or the like, for example.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a display area having a plurality of pixels arranged in a matrix, each of the plurality of pixels including a light emitting element and a transistor; and
a touch sensor provided over the display area;
wherein the touch sensor includes a plurality of first electrodes and a plurality of second electrodes, and
the plurality of first electrodes has a shape of ring-shaped electrodes connected to each other.

2. The display device according to claim 1, wherein
the plurality of second electrodes has a shape of ring-shaped electrodes connected to each other.

3. The display device according to claim 1, further comprising an internal electrode inside the ring-shaped electrode.

4. The display device according to claim 3, wherein
the ring-shaped electrode and the internal electrode are formed in a same layer.

5. The display device according to claim 1, wherein
the ring-shaped electrode has a cut-out part,
the second electrode has a protruding part, and
the protruding part enters an inside of the ring-shaped electrode through the cut-out part.

6. The display device according to claim 1, wherein
the touch sensor further comprises:
a touch drive circuit which input a drive signal to the plurality of second electrodes; and
a detection circuit which acquires fluctuation in potential of the plurality of first electrodes.

7. The display device according to claim 1, further comprising
a sealing layer which covers the display area,
wherein the plurality of first electrodes and the plurality of second electrodes are formed over the sealing film.
